(19) United States
(12) Patent Application Publication
(10) Pub. No.: US 2025/0386707 A1
(43) Pub. Date: Dec. 18, 2025

(54) DISPLAY DEVICE, METHOD OF MANUFACTURING THE SAME AND ELECTRONIC DEVICE INCLUDING THE SAME

(71) Applicant: Samsung Display Co., LTD., Yongin-si (KR)

(72) Inventor: Hyun Eok SHIN, Yongin-si (KR)

(73) Assignee: Samsung Display Co., LTD., Yongin-si (KR)

(21) Appl. No.: 19/089,606

(22) Filed: Mar. 25, 2025

(30) Foreign Application Priority Data
Jun. 18, 2024 (KR) 10-2024-0078741
Aug. 23, 2024 (KR) 10-2024-0113597

(51) Int. Cl. H10K 59/80; H10H 29/01; H10H 29/30; H10H 29/80; H10K 59/12; H10K 71/60; H10K 102/00; H10K 102/10

(52) U.S. Cl. CPC H10K 59/80522; H10H 29/011; H10H 29/012; H10H 29/032; H10H 29/30; H10H 29/8323; H10K 59/1201; H10K 71/60; H10K 2102/103; H10K 2102/351

(57) ABSTRACT

A display device includes an anode electrode disposed on a substrate; an insulating layer disposed on the substrate, the insulating layer covering an edge of the anode electrode, and the insulating layer having a first opening overlapping the anode electrode; a thin film layer disposed on the insulating layer, the thin film layer including a tip protruding toward the first opening, and the thin film layer having a second opening defined by the tip; a light-emitting layer disposed on the anode electrode, the light-emitting layer disposed inside of the first opening, and directly contacting the tip of the thin film layer; and a cathode electrode disposed over the light-emitting layer and the thin film layer.

### CROSS-REFERENCE TO RELATED APPLICATION(S)

This application claims priority to and benefits of Korean patent application No. 10-2024-0078741 under 35 U.S.C. § 119 filed on Jun. 18, 2024, Korean patent application No. 10-2024-0113597 under 35 U.S.C. § 119 filed on Aug. 23, 2024, in the Korean Intellectual Property Office, the entire contents of which are incorporated herein by reference.

### BACKGROUND

### 1. Technical Field

Embodiments relate to a display device. By way of example, embodiments relate to a display device, a method of manufacturing the display device, and an electronic device including the display device.

### 2. Description of the Related Art

With the development of information technology, the importance of display devices, which are the medium of connection between users and information, is being highlighted. In response, the use of display devices such as liquid crystal display devices and organic light emitting display devices is increasing.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

An object to be achieved by embodiments of the disclosure is to provide a highly reliable display device by preventing disconnection of a cathode electrode and reducing the resistance of the cathode electrode.

Another object to be achieved by embodiments of the disclosure is to provide a method of manufacturing the display device.

Objects of the disclosure are not limited to the objects mentioned above, and other technical objects not mentioned may be clearly understood by a person skilled in the art from the following description.

A display device according to embodiments may include an anode electrode disposed on a substrate; an insulating layer disposed on the substrate, the insulating layer covering an edge of the anode electrode, and the insulating layer having a first opening overlapping the anode electrode; a thin film layer disposed on the insulating layer, the thin film layer may include a tip protruding toward the first opening, and the thin film layer having a second opening defined by the tip; a light-emitting layer disposed on the anode electrode, the light-emitting layer disposed inside of the first opening, and directly contacting the tip of the thin film layer; and a cathode electrode disposed over the light-emitting layer and the thin film layer.

In an embodiment, a thickness of the insulating layer disposed between the anode electrode and the thin film layer may be less than or equal to a thickness of the light-emitting layer.

In an embodiment, the thickness of the insulating layer disposed between the anode electrode and the thin film layer may be equal to or less than about 1500 Å.

In an embodiment, the thin film layer may include a metal.

In an embodiment, the thin film layer may include at least one of niobium, titanium, tantalum, and titanium nitride.

In an embodiment, the insulating layer may include an inorganic material.

In an embodiment, the insulating layer may include at least one of silicon oxide and silicon nitride.

In an embodiment, the display device may further include an auxiliary electrode extending over the cathode electrode.

In an embodiment, the auxiliary electrode may include a transparent conductive oxide. A display device according to embodiments may include anode electrodes disposed on a substrate and spaced apart from each other; an insulating layer disposed on the substrate, the insulating layer covering edges of the anode electrodes, and the insulating layer having first openings overlapping the anode electrodes, respectively; a thin film layer disposed on the insulating layer, the thin film layer may include tips protruding toward the first openings, and the thin film layer having second openings defined by the tips, respectively; light-emitting layers disposed on the anode electrodes, respectively, spaced apart from each other, the light-emitting layers disposed inside of the first openings, respectively, and directly contacting the tips of the thin film layer, respectively; and a cathode electrode disposed over the light-emitting layers and the thin film layer.

In an embodiment, a thickness of the insulating layer disposed between the anode electrodes and the thin film layer may be less than or equal to a smallest thickness among thicknesses of the light-emitting layers.

In an embodiment, the display device may further include an auxiliary electrode extending over the cathode electrode.

A method of manufacturing a display device according to embodiments may include forming an anode electrode on a substrate; forming an insulating layer covering an edge of the anode electrode, and the insulating layer having a first opening overlapping the anode electrode on the substrate; forming a thin film layer which may include a tip protruding toward the first opening, and the thin film layer having a second opening defined by the tip on the insulating layer; forming a light-emitting layer disposed inside of the first opening and directly contacting the tip of the thin film layer on the anode electrode; and forming a cathode electrode disposed over the light-emitting layer and the thin film layer.

In an embodiment, a thickness of the light-emitting layer may be formed greater than a thickness of the insulating layer disposed between the anode electrode and the thin film layer.

In an embodiment, the forming of the light-emitting layer may include forming a preliminary light-emitting layer extending over the anode electrode and the thin film layer; forming a sacrificial layer extending over the preliminary light-emitting layer; forming a photoresist pattern overlapping the second opening on the sacrificial layer; partially etching the sacrificial layer using the photoresist pattern; forming the light-emitting layer by partially etching the preliminary light-emitting layer using the photoresist pattern; removing the photoresist pattern; and removing the sacrificial layer.

In an embodiment, the sacrificial layer may be formed of at least one of aluminum and silver.

In an embodiment, the sacrificial layer and the preliminary light-emitting layer may be etched under different conditions.

In an embodiment, the forming of the sacrificial layer may be performed through a thermal deposition process.

In an embodiment, the method may further include forming an auxiliary electrode overlapping the cathode electrode.

In an embodiment, the forming of the auxiliary electrode may be performed through a sputtering process.

An electronic device according to embodiments may include a display device including: an anode electrode disposed on a substrate; an insulating layer disposed on the substrate, the insulating layer covering an edge of the anode electrode, and the insulating layer having a first opening overlapping the anode electrode; a thin film layer disposed on the insulating layer, the thin film layer including a tip protruding toward the first opening, and the thin film layer having a second opening defined by the tip; a light-emitting layer disposed on the anode electrode, the light-emitting layer disposed inside of the first opening, and directly contacting the tip of the thin film layer; and a cathode electrode disposed over the light-emitting layer and the thin film layer.

Details of other embodiments are included in the detailed description of the disclosure and drawings.

According to the above-described embodiment, since the thin film layer and the first to third light-emitting layers are connected as a whole, disconnection of the cathode electrode and the auxiliary electrode may be prevented without a separate configuration. Accordingly, the configuration of the display device may be simplified. Since the thin film layer is composed of a metal with low resistivity, the overall resistance of the cathode electrode in direct contact with the thin film layer may be reduced.

Effects of embodiments are not limited by the above, and a wider variety of effects are included herein.

### BRIEF DESCRIPTION OF THE DRAWINGS

The above and other aspects and features of the disclosure will become more apparent by describing in detail embodiments thereof with reference to the attached drawings, in which:

FIG. 1 is a block diagram illustrating an embodiment of a display device.

FIG. 2 is a block diagram illustrating an embodiment of any of sub-pixels of FIG. 1.

FIG. 3 is a schematic plan view illustrating an embodiment of the display panel of FIG. 1.

FIG. 4 is a schematic cross-sectional diagram illustrating an embodiment of the display panel of FIG. 3.

FIG. 5 is a schematic cross-sectional diagram illustrating an embodiment of the display panel of FIG. 3.

FIG. 6 is a schematic plan view illustrating an embodiment of any of the pixels of FIG. 3.

FIG. 7 is a schematic cross-sectional diagram taken along the I-I′ line of FIG. 6 according to an embodiment.

FIGS. 8 to 19 are diagrams illustrating a method of manufacturing a display device according to embodiments.

FIG. 20 is a block diagram illustrating an embodiment of a display system.

FIG. 21 is a schematic perspective view illustrating an example of the application of the display system of FIG. 20.

FIG. 22 is a diagram illustrating a head-mounted display device worn by a user of FIG. 21.

### DETAILED DESCRIPTION OF THE EMBODIMENTS

The disclosure may be modified in various ways and may have various forms, and embodiments are illustrated in the drawings and described in detail in the following. However, it is not intended to limit the disclosure to a particular form of the disclosure, and should be understood to include all modifications, equivalents, or substitutions that fall within the scope of ideas and technology of the disclosure.

In describing each drawing, similar reference numerals are used for similar components. In the accompanying drawings, the dimensions of the structures are shown enlarged from the actual size for the clarity of the disclosure.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

Terms such as first and second may be used to describe various components, but the components should not be limited by the above terms. The above terms are used only for the purpose of distinguishing one component from another. For example, a first component may be named as a second component without departing from the scope of the disclosure, and similarly, the second component may be named the first component.

In this application, the terms “comprise”, “include” or “have” should be understood to designate the existence of the features, numbers, steps, operations, components, parts, or combinations thereof described in the specification, and not to preclude the possibility of the existence or addition of one or more other features or numbers, steps, operations, components, parts, or combinations thereof.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

When a part such as a layer, a film, an area, or a plate is referred to as being “on” another part, this includes not only the case where the part is “directly above” the other part, but also the case where there is another part in between. In the specification, when a part such as a layer, a film, an area, or a plate is referred to as being formed on another part, the direction in which the part is formed is not limited to an upward direction, but includes formation in a lateral or downward direction. Conversely, when a part such as a layer, a film, an area, or a plate is referred to as being “below” another part, this includes not only the case where the part is “just below” the other part, but also the case where there is another part in between.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

Embodiments may be described and illustrated in the accompanying drawings in terms of functional blocks, units, and/or modules.

Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies.

In the case of the blocks, units, and/or modules being implemented by microprocessors or other similar hardware, they may be programmed and controlled using software (for example, microcode) to perform various functions discussed herein and may optionally be driven by firmware and/or software.

It is also contemplated that each block, unit, and/or module may be implemented by dedicated hardware, or as a combination of dedicated hardware to perform some functions and a processor (for example, one or more programmed microprocessors and associated circuitry) to perform other functions.

Each block, unit, and/or module of embodiments may be physically separated into two or more interacting and discrete blocks, units, and/or modules without departing from the scope of the disclosure.

Further, the blocks, units, and/or modules of embodiments may be physically combined into more complex blocks, units, and/or modules without departing from the scope of the disclosure.

Hereinafter, with reference to the accompanying drawings, embodiments and other matters necessary for those skilled in the art to readily understand the disclosure will be described in detail.

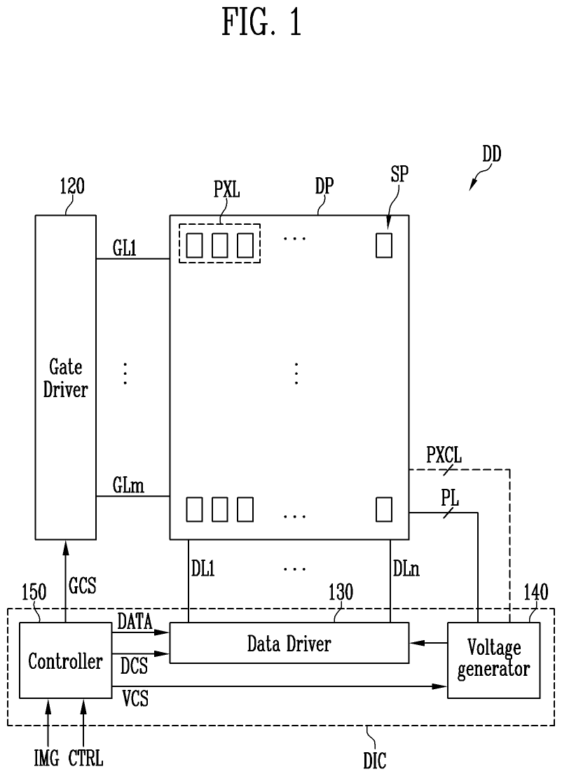

FIG. 1 is a block diagram illustrating an embodiment of a display device.

Referring to FIG. 1, a display device DD may include a display panel DP, a gate driver 120, a data driver 130, a voltage generator 140, and a controller 150.

The display panel DP may include sub-pixels SP. The sub-pixels SP may be connected to the gate driver 120 via first to m-th gate lines GL1 to GLm. The sub-pixels SP may be connected to the data driver 130 via first to n-th data lines DL1 to DLn.

The sub-pixels SP may generate light of two or more colors. For example, each of the sub-pixels SP may generate light such as red, green, blue, cyan, magenta, yellow, etc.

Two or more sub-pixels of the sub-pixels SP may form a single pixel PXL. For example, the pixel PXL may include three sub-pixels, as shown in FIG. 1. In this way, the pixel PXL may emit light of various colors and different luminance depending on the combination of light emitted from the sub-pixels included therein.

The gate driver 120 may be connected to the sub-pixels SP disposed in a row direction via the first to m-th gate lines GL1 to GLm. The gate driver 120 may output gate signals to the first to m-th gate lines GL1 to GLm in response to a gate control signal GCS. In an embodiment, the gate control signal GCS may include a start signal indicating the start of each frame, and a horizontal synchronization signal.

The gate driver 120 may be disposed on one side or on a side of the display panel DP. However, embodiments are not limited thereto. For example, the gate driver 120 may be divided into two or more physically and/or logically distinct drivers, and such drivers may be disposed on one side or on a side of the display panel DP and on the other side of the display panel DP as opposed to one side or on a side. Thus, the gate driver 120 may be disposed around the display panel DP in various forms depending on embodiments.

The data driver 130 may be connected to the sub-pixels SP disposed in a column direction through the first to n-th data lines DL1 to DLn. The data driver 130 may receive image data DATA and a data control signal DCS from the controller 150. The data driver 130 operates in response to the data control signal DCS. In an embodiment, the data control signal DCS may include a source start signal, a source shift clock, a source output enabling signal, and the like within the spirit and the scope of the disclosure.

The data driver 130 may receive voltages from the voltage generator 140. Using the received voltages, the data driver 130 may apply data signals with graded voltages corresponding to the image data DATA to the first to n-th data lines DL1 to DLn. In case that a gate signal is applied to each of the first to m-th gate lines GL1 to GLm, the data signals corresponding to the image data DATA may be applied to the data lines DL1 to DLn. Accordingly, the sub-pixels SP may generate light corresponding to the data signals, and the display panel DP may display the image.

In an embodiment, the gate driver 120 and the data driver 130 may include complementary metal-oxide semiconductor (CMOS) circuit elements.

The voltage generator 140 may operate in response to a voltage control signal VCS from the controller 150. The voltage generator 140 may generate voltages and provide the generated voltages to components of the display device DD such as the gate driver 120, the data driver 130, and the controller 150. The voltage generator 140 may generate voltages by receiving input voltages from the outside of the display device DD and regulating the received voltages.

The voltage generator 140 may generate a first power voltage and a second power voltage. The generated first and second power voltages may be provided to the sub-pixels SP via power lines PL. In an embodiment, at least one of the first and second power voltages may be provided from the outside the display device DD.

The voltage generator 140 may provide a variety of voltages and/or signals. For example, the voltage generator 140 may provide one or more initialization voltages applied to the sub-pixels SP. For example, in a sensing operation to sense the electrical properties of transistors and/or light-emitting elements of the sub-pixels SP, a selectable reference voltage may be applied to the first to n-th data lines DL1 to DLn, and the voltage generator 140 may generate the reference voltage and transmit the reference voltage to the data driver 130. For example, during the display operation to display an image on the display panel DP, common pixel control signals may be applied to the sub-pixels SP, and the voltage generator 140 may generate the pixel control signals. In an embodiment, the voltage generator 140 may provide pixel control signals to the sub-pixels SP via pixel control lines PXCL. FIG. 1 shows that the pixel control lines PXCL are connected between the voltage generator 140 and the display panel DP, but embodiments are not limited thereto. For example, the pixel control lines PXCL may be connected between the gate driver 120 and the display panel DP. The pixel control signals may be transmitted from the voltage generator 140 to the pixel control lines PXCL via the gate driver 120.

The controller 150 may control all operations of the display device DD. The controller 150 may receive input image data IMG and its corresponding control signal CTRL from the outside. The controller 150 may respond to a control signal CTRL and provide a gate control signal GCS, a data control signal DCS, and a voltage control signal VCS.

The controller 150 may convert the input image data IMG to fit the display device DD or the display panel DP and output the converted image data. In an embodiment, the controller 150 may align the input image data IMG to suitably fit the sub-pixels SP of a row unit and output the image data DATA.

Two or more of the data driver 130, the voltage generator 140, and the controller 150 may be mounted in a single integrated circuit. As shown in FIG. 1, the data driver 130, the voltage generator 140, and the controller 150 may be included in a driver integrated circuit DIC. The data driver 130, the voltage generator 140, and the controller 150 may be functionally distinct components in one driver integrated circuit DIC. In an embodiment, at least one of the data driver 130, the voltage generator 140, and the controller 150 may be provided as a separate component from the driver integrated circuit DIC.

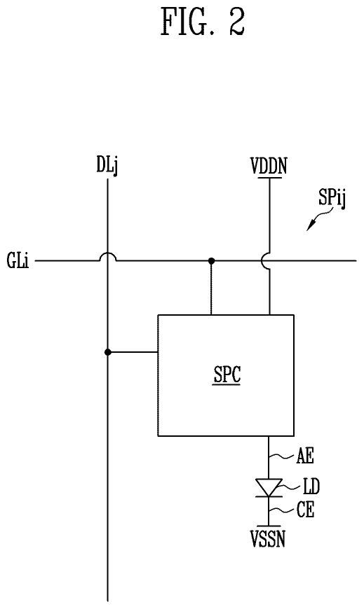

FIG. 2 is a block diagram illustrating an embodiment of any one of the sub-pixels of FIG. 1. Referring to FIG. 2, a sub-pixel SPij disposed in an i-th row where i is greater than or equal to 1 and less than or equal to m and a j-th column where j is greater than or equal to 1 and less than or equal to n among the sub-pixels SP of FIG. 1 is illustrated.

Referring to FIG. 2, the sub-pixel SPij may include a sub-pixel circuit SPC and a light-emitting element LD.

The light-emitting element LD may be connected between a first power voltage node VDDN and a second power voltage node VSSN. The first power voltage node VDDN may be connected to one of the power lines PL of FIG. 1 and may receive the first power voltage. The second power voltage node VSSN may be connected to another of the power lines PL in FIG. 1 and receive the second power voltage. The first power voltage may have a higher voltage level than the second power voltage.

The light-emitting element LD may be connected between an anode electrode AE and a cathode electrode CE. The anode electrode AE may be connected to the first power voltage node VDDN via the sub-pixel circuit SPC. For example, the anode electrode AE may be connected to the first power voltage node VDDN via one or more transistors included in the sub-pixel circuit SPC. The cathode electrode CE may be connected to the second power voltage node VSSN. The light-emitting element LD may emit light according to the current flowing from the anode electrode AE to the cathode electrode CE.

The sub-pixel circuit SPC may be connected to an i-th gate line GLi among the first to m-th gate lines GL1 to GLm of FIG. 1 and a j-th data line DLj among the first to n-th data lines DL1 to DLn of FIG. 1. In response to the gate signal received through the i-th gate line GLi, the sub-pixel circuit SPC may control the light-emitting element LD to emit light according to the data signal received through the j-th data line DLj. In an embodiment, the sub-pixel circuit SPC may be further connected to the pixel control lines PXCL of FIG. 1. The sub-pixel circuit SPC may control the light-emitting element LD by responding more to the pixel control signals received through the pixel control lines PXCL.

For these operations, the sub-pixel circuit SPC may include circuit elements, such as transistors and one or more capacitors.

The transistors in the sub-pixel circuit SPC may include P-type transistors and/or N-type transistors. In an embodiment, the transistors of the sub-pixel circuit SPC may include a Metal Oxide Silicon Field Effect Transistor MOSFET. In an embodiment, the transistors of the sub-pixel circuit SPC may include amorphous silicon semiconductors, monocrystalline silicon semiconductors, polycrystalline silicon semiconductors, oxide semiconductors, and so on.

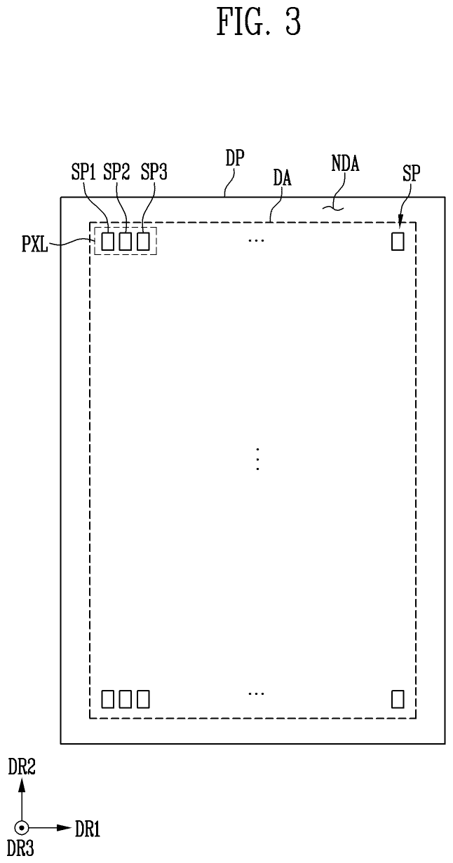

FIG. 3 is a schematic plan view illustrating an embodiment of the display panel of FIG. 1.

Referring to FIG. 3, the display panel DP may include a display area DA and a non-display area NDA. The display panel DP displays the image through the display area DA. The non-display area NDA may be disposed around the display area DA.

The display panel DP may include the sub-pixels SP in the display area DA. The sub-pixels SP may be disposed along a first direction DR1 and a second direction DR2 intersecting the first direction DR1. For example, the sub-pixels SP may be disposed in a matrix form along the first direction DR1 and the second direction DR2. As another example, the sub-pixels SP may be disposed in a zigzag pattern along the first direction DR1 and the second direction DR2. The arrangement of the sub-pixels SP may vary according to embodiments. The first direction DR1 may be the row direction, and the second direction DR2 may be the column direction.

Two or more sub-pixels of the sub-pixels SP may form a single pixel PXL. In FIG. 3, the pixel PXL is shown to include three sub-pixels SP1 to SP3, but embodiments are not limited to this example. For example, a pixel PXL may include two sub-pixels. Hereinafter, for the convenience of explanation, it is assumed that the pixels PXL include the first to third sub-pixels SP1 to SP3.

Each of the first to third sub-pixels SP1 to SP3 may generate one of a variety of colors such as red, green, blue, cyan, magenta, yellow, etc. For the sake of clarity and conciseness, it is assumed that the first sub-pixel SP1 is configured to generate red-colored light, the second sub-pixel SP2 is configured to generate blue-colored light, and the third sub-pixel SP3 is configured to generate green-colored light.

Each of the first to third sub-pixels SP1 to SP3 may include at least one light-emitting element that generates light. In an embodiment, the light-emitting elements of the first to third sub-pixels SP1 to SP3 may generate light of different colors. For example, the light-emitting elements of the first to third sub-pixels SP1 to SP3 may generate red, blue, and green light, respectively. In an embodiment, the light-emitting elements of the first to third sub-pixels SP1 to SP3 may generate light of the same color. For example, the light-emitting elements of the first to third sub-pixels SP1 to SP3 may generate blue colored light.

As the display panel DP, a display panel capable of self-emitting light, such as an LED display panel that uses a microscale or nanoscale light-emitting diode as a light-emitting element, or an organic light emitting display panel OLED panel that uses an organic light-emitting diode as a light-emitting element, may be used.

In the non-display area NDA, a component for controlling the sub-pixels SP may be disposed. Wiring connected with the sub-pixels SP, for example, the first to m-th gate lines GL1 to GLm, the first to n-th data lines DL1 to DLn, the power lines PL, and the pixel control lines PXCL may be disposed in the non-display area NDA.

At least one of the gate driver 120, the data driver 130, the voltage generator 140, and the controller 150 of FIG. 1 may be disposed in the non-display area NDA of the display panel DP. In an embodiment, the gate driver 120 may be disposed in the non-display area NDA. In such a case, the data driver 130, the voltage generator 140, and the controller 150 may be implemented as the driver integrated circuit DIC of FIG. 1 separated from the display panel DP, and the driver integrated circuit DIC may be connected to the wiring disposed in the non-display area NDA. In an embodiment, the gate driver 120 may be implemented as an integrated circuit distinct from the display panel DP together with the data driver 130, the voltage generator 140, and the controller 150.

In an embodiment, the display area DA may have a variety of shapes. The display area DA may have the shape of a closed loop including straight and/or curved sides. For example, a display area DA may have shapes such as polygons, circles, semicircles, ellipses, etc.

In an embodiment, the display panel DP may have a flat display surface. In an embodiment, the display panel DP may have at least a partially rounded display surface. In an embodiment, the display panel DP may be bendable, foldable, or rollable. In these cases, the substrate of the display panel DP and/or the display panel DP may include materials having flexible properties.

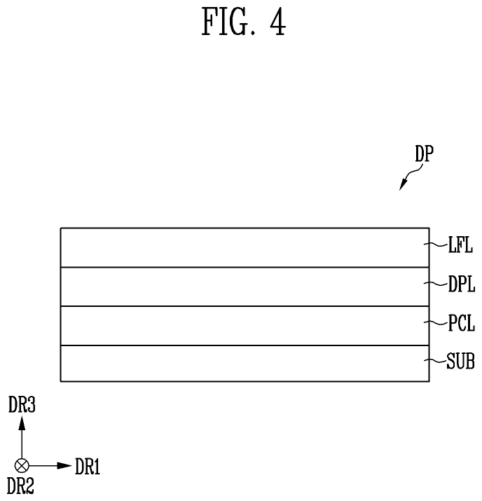

FIG. 4 is a schematic cross-sectional diagram illustrating an embodiment of the display panel of FIG. 3.

Referring to FIG. 4, the display panel DP may include a substrate SUB, and a pixel circuit layer PCL, a display element layer DPL, and a light functional layer LFL that may be sequentially stacked on the substrate SUB in a third direction DR3 intersecting with the first and second directions DR1 and DR2.

The substrate SUB may be made up of insulating materials such as glass and resin. For example, a substrate may include a glass substrate. As another example, the substrate SUB may include a polyimide substrate PI. As another example, the substrate SUB may include a silicon wafer substrate formed using semiconductor processes.

In an embodiment, the substrate SUB may be formed of a flexible material that allows bending or folding, and may have a single-layer structure or a multi-layered structure. For example, the flexible material may include at least one of the following: polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers, and semiconductor patterns and conductive patterns disposed between the insulating layers. The conductive patterns in the pixel circuit layer PCL may function as circuit elements, wiring, and so on.

The circuit elements of the pixel circuit layer PCL may include the sub-pixel circuit SPC see FIG. 2 for each of the sub-pixels SP of FIG. 3. In other words, circuit elements of the pixel circuit layer PCL may be provided as transistors and one or more capacitors of the sub-pixel circuit SPC.

The wirings of the pixel circuit layer PCL may include wirings connected to the sub-pixels SP. The wirings of the pixel circuit layer PCL may include various signal lines and/or voltage lines required to drive the display element layer DPL.

The display element layer DPL may be disposed on the pixel circuit layer PCL. The display element layer DPL may include light-emitting elements of the sub-pixels SP.

The light functional layer LFL may be disposed on the display element layer DPL. The light functional layer LFL may include light conversion patterns with color-changing particles and/or scattering particles. For example, the color-changing particles may include quantum dots. The quantum dots may change the wavelength (or color) of light emitted from the display element layer DPL. The light functional layer LFL may further include light scattering patterns having scattering particles. In an embodiment, the light conversion patterns and the light scattering patterns may be omitted.

The light functional layer LFL may further include a color filter layer including color filters. The color filter may selectively transmit light of a given wavelength (or a given color). In an embodiment, the color filter layer may be omitted.

A window may be provided on the light functional layer LFL to protect the exposed surface (or upper surface) of the display panel DP. The window may protect the display panel DP from external shocks. The window may be bonded to the light functional layer LFL via an optically transparent adhesive member. The window may have a multi-layer structure selected from a glass substrate, a plastic film, or a plastic substrate. These multi-layered structures may be formed through a continuous process or an adhesive process using an adhesive layer. All or part of a window may be flexible.

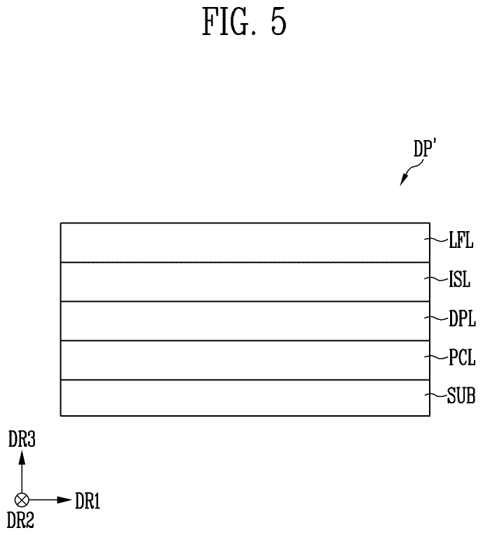

FIG. 5 is a schematic cross-sectional diagram illustrating an embodiment of the display panel of FIG. 3.

Referring to FIG. 5, a display panel DP′ may include a substrate SUB, a pixel circuit layer PCL, a display element layer DPL, an input sensing layer ISL, and a light functional layer LFL. The substrate SUB, the pixel circuit layer PCL, the display element layer DPL, and the light functional layer LFL are configured similarly to the substrate SUB, the pixel circuit layer PCL, the display element layer DPL, and the light functional layer LFL described with reference to FIG. 4. In the following, redundant explanations are omitted.

The input sensing layer ISL may sense a user input to the upper surface or display surface of the display panel DP′. The input sensing layer ISL may include configurations suitable for detecting external objects such as the user's hand or a pen. For example, the input sensing layer ISL may include touch electrodes.

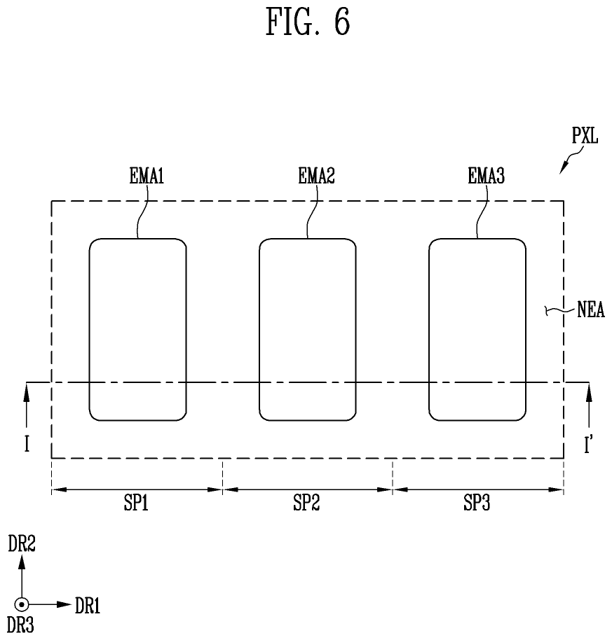

FIG. 6 is a schematic plan view illustrating an embodiment of any one of the pixels of FIG. 3.

Referring to FIG. 6, a first pixel PXL1 may include the first to third sub-pixels SP1 to SP3 disposed in the first direction DR1.

The first sub-pixel SP1 may include a first light-emitting area EMA1 and a non-light-emitting area NEA around the first light-emitting area EMA1. The second sub-pixel SP2 may include a second light-emitting area EMA2 and a non-light-emitting area NEA around the second light-emitting area EMA2. The third sub-pixel SP3 may include a third light-emitting area EMA3 and a non-light-emitting area NEA around the third light-emitting area EMA3.

The first light-emitting area EMA1 may be an area in which light is emitted from a part of the light-emitting element corresponding to the first sub-pixel SP1. The second light-emitting area EMA2 may be an area in which light is emitted from a part of the light-emitting element corresponding to the second sub-pixel SP2. The third light-emitting area EMA3 may be an area in which light is emitted from a part of the light-emitting element corresponding to the third sub-pixel SP3.

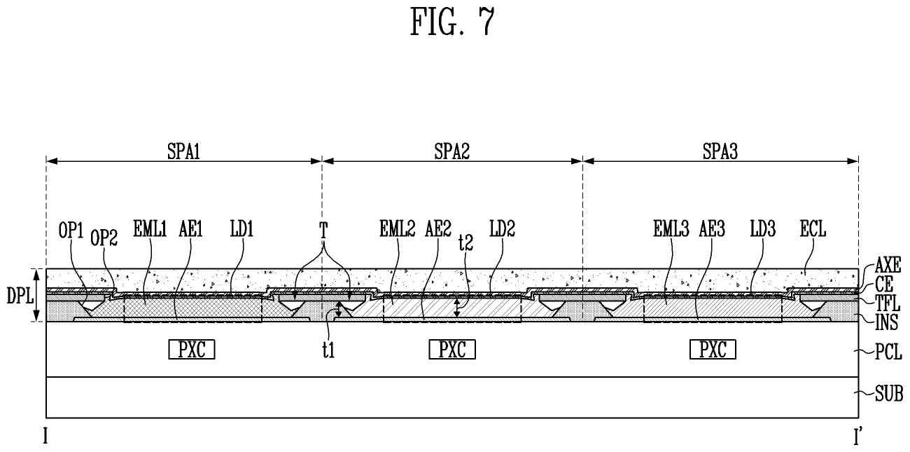

FIG. 7 is a schematic cross-sectional diagram taken along the I-I′ line of FIG. 6 according to an embodiment. FIG. 7 may be a diagram illustrating only the substrate SUB, the pixel circuit layer PCL, and the display element layer DPL of FIG. 4 or FIG. 5.

Referring to FIG. 7, the display panel may include first to third sub-pixel areas SPA1 to SPA3 in which the first to third sub-pixels SP1 to SP3 of FIG. 3 are disposed respectively.

The pixel circuit layer PCL may be disposed on the substrate SUB. The pixel circuit layer PCL may further include insulating layers, and semiconductor patterns and conductive patterns disposed between the insulating layers. The semiconductor patterns and the conductive patterns may form circuit elements PXC. Each of the circuit elements PXC may be provided to transistors and capacitors of each of the sub-pixels.

The display element layer DPL may be disposed on the pixel circuit layer PCL. The display element layer DPL may include first to third anode electrodes AE1 to AE3, an insulating layer INS, a thin film layers TFL, first to third light-emitting layers EML1 to EML3, a cathode electrodes CE, an auxiliary electrode AXE, and an encapsulation layer ECL.

The first to third anode electrodes AE1 to AE3 may be disposed on the pixel circuit layer PCL. The first to third anode electrodes AE1 to AE3 may be spaced from each other and may be disposed in the first to third sub-pixel areas SPA1 to SPA3. Each of the first to third anode electrodes AE1 to AE3 may be provided as the anode electrode AE connected to the sub-pixel circuit SPC (see FIG. 2) of each of the first to third sub-pixels SP1 to SP3 of FIG. 3.

The insulating layer INS may be disposed on the pixel circuit layer PCL and the first to third anode electrodes AE1 to AE3. The insulating layer INS may cover the edge of each of the first to third anode electrodes AE1 to AE3. The insulating layer INS may have a first opening OP1 that overlaps each of the first to third anode electrodes AE1 to AE3. In other words, the insulating layer INS may expose each of the first to third anode electrodes AE1 to AE3 through the first openings OP1.

In an embodiment, the insulating layer INS may include inorganic materials. For example, the insulating layer INS may include at least one of silicon oxide and silicon nitride. The insulating layer INS may have a single-layer structure or a multi-layer structure.

A thin film layer TFL may be disposed on the insulating layer INS. The thin film layer TFL may include tips T protruding toward the first openings OP1. The thin film layer TFL may have second openings OP2, each defined by the tips T. The area of the second opening OP2 may be smaller than the area of the first opening OP1 defined by the upper surface of the insulating layer INS that is in contact with the thin film layer TFL. Accordingly, the tip T of the thin film layer TFL may have a shape protruding from the insulating layer INS to the inner side of the first opening OP1.

In an embodiment, the thin film layer TFL may include metals. For example, a thin film layer TFL may include at least one of niobium, titanium, tantalum, and titanium nitride. By way of example, the thin film layer TFL may include niobium with the lowest resistivity.

The first to third light-emitting layers EML1 to EML3 may be disposed on the first to third anode electrodes AE1 to AE3 respectively. The first to third light-emitting layers EML1 to EML3 are spaced apart from each other and may be disposed inside the first opening OP1, respectively.

In an embodiment, the first to third light-emitting layers EML1 to EML3 may each be directly connected to the tips T of the thin film layer TFL. In other words, each of the first to third light-emitting layers EML1 to EML3 may be in direct contact with the tip T of the thin film layer TFL, and each of the first to third light-emitting layers EML1 to EML3 and the thin film layer TFL may be connected continuously without being spaced apart from each other. Accordingly, the first to third light-emitting layers EML1 to EML3 and the thin film layer TFL may be connected to each other continuously on the first to third sub-pixel areas SPA1 to SPA3.

In an embodiment, the thickness t1 of the part of the insulating layer INS, which is disposed between each of the first to third anode electrodes AE1 to AE3 and the thin film layer TFL, may be less than or equal to the thickness t2 of each of the first to third light-emitting layers EML1 to EML3. At this time, the thickness t1 of the part of the insulating layer INS, which is disposed between each of the first to third anode electrodes AE1 to AE3 and the thin film layer TFL, may be less than or equal to the smallest thickness of the thicknesses of the first to third light-emitting layers EML1 to EML3. Thus, the thickness t1 of the part of the insulating layer INS, which is disposed between each of the first to third anode electrodes AE1 to AE3 and the thin film layer TFL, may always be less than the thickness of the first to third light-emitting layers EML1 to EML3. Accordingly, the thin film layer TFL disposed on the insulating layer INS may be stably connected to the first to third anode electrodes AE1 to AE3.

If the thickness t1 of the part of the insulating layer INS, which is disposed between each of the first to third anode electrodes AE1 to AE3 and the thin film layer TFL, is greater than the thickness t2 of each of the first to third light-emitting layers EML1 to EML3, the tips

T of the thin film layer TFL and the first to third light-emitting layers EML1 to EML3 are spaced farther apart, so that in case that the first to third light-emitting layers EML1 to EML3 are deposited respectively, the first to third light-emitting layers EML1 to EML3 may not be connected to the tips T of the thin film layer TFL, and may flow down and be deposited only in the first openings OP1, and the first to third light-emitting layers EML1 to EML3 and the thin film layer TFL may be spaced apart from each other. Thus, for the stable connection of the thin film layer TFL and the first to third anode electrodes AE1 to AE3, the thickness t1 of the part of the insulating layer INS, which is disposed between each of the first to third anode electrodes AE1 to AE3 and the thin film layer TFL, may be less than or equal to the smallest thickness among thicknesses the first to third light-emitting layers EML1 to EML3. As the first to third anode electrodes AE1 to AE3 and the thin film layer TFL are stably connected without separation from each other, the first to third anode electrodes AE1 to AE3, and the cathode electrode CE and the auxiliary electrode AXE, which are disposed on the thin film layer TFL, may be seamlessly extended as a whole.

For example, the thickness t1 of the part of the insulating layer INS, which is disposed between each of the first to third anode electrodes AE1 to AE3 and the thin film layer TFL, may be about 1500 Å or less. At this time, the smallest thickness of the first to third light-emitting layers EML1 to EML3 may be about 1500 Å. As described above, if the thickness t1 of the part of the insulating layer INS, which is disposed between each of the first to third anode electrodes AE1 to AE3 and the thin film layer TFL, is greater than about 1500 Å, the first to third light-emitting layers EML1 to EML3 may be spaced apart from the tips T of the thin film layer TFL without being connected respectively.

A cathode electrode CE may be disposed on a thin film layer TFL and first to third light-emitting layers EML1 to EML3. The cathode electrode CE may be disposed overall on the first to third sub-pixel areas SPA1 to SPA3.

Accordingly, the first anode electrode AE1, the first light-emitting layer EML1, and the cathode electrode CE, which are disposed in the first sub-pixel area SPA1, may form a first light-emitting element LD1. A second anode electrode AE2, a second light-emitting layer EML2, and a cathode electrode CE, which are disposed in the second sub-pixel area SPA2, may form a second light-emitting element LD2. A third anode electrode AE3, a third light-emitting layer EML3, and a cathode electrode CE, which are disposed in the third sub-pixel area SPA3, may form a third light-emitting element LD3.

The auxiliary electrode AXE may be disposed on the cathode electrode CE. The auxiliary electrode AXE may overall extend on the cathode electrode CE and overall overlap the cathode electrode CE.

Accordingly, even if the cathode electrode CE is partially disconnected due to the profile of the configurations disposed below the cathode electrode CE, the auxiliary electrode AXE is in direct contact with the cathode electrode CE and overall extends, thus overall connecting the cathode electrode CE.

In an embodiment, the auxiliary electrode AXE may include a transparent conductive oxide. For example, the auxiliary electrode AXE may include at least one of indium zinc oxide and indium tin oxide.

The encapsulation layer ECL may be disposed on the auxiliary electrode AXE. The encapsulation layer ECL may cover the auxiliary electrode AXE in its entirety and may protect the auxiliary electrode AXE.

In an embodiment, the thin film layer TFL and the first to third light-emitting layers EML1 to EML3 are connected as a whole, so that disconnection of the cathode electrode CE and the auxiliary electrode AXE may be prevented without additional configuration. Accordingly, the configuration of the display device may be simplified. Since the thin film layer TFL is composed of a metal with a low resistivity, the overall resistance of the cathode electrode CE in direct contact with the thin film layer TFL may be reduced.

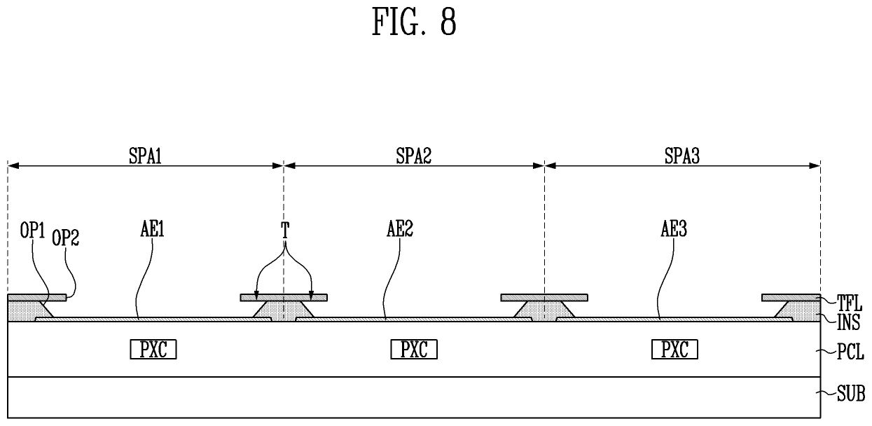

FIGS. 8 to 19 are diagrams illustrating a method of manufacturing a display device according to embodiments. FIGS. 8 to 19 show a method of manufacturing the display device DD according to the embodiment described above with reference to FIGS. 1 to 7. Therefore, any information that may overlap the foregoing may be briefly explained or may be omitted.

Referring to FIG. 8, the pixel circuit layer PCL may be formed on the substrate SUB. The first to third anode electrodes AE1 to AE3 overlapping the first to third sub-pixel areas SPA1 to SPA3, respectively, may be formed on the pixel circuit layer PCL.

The insulating layer INS may be formed on the first to third anode electrodes AE1 to AE3. The first openings OP1, which overlap the first to third anode electrodes AE1 to AE3 respectively and partially expose the first to third anode electrodes AE1 to AE3 respectively, may be formed on the insulating layer INS. The insulating layer INS, which is adjacent to the first openings OP1, may cover the edges of the first to third anode electrodes AE1 to AE3 respectively. In an embodiment, the insulating layer INS may be formed from an inorganic material.

The thin film layer TFL may be formed on the insulating layer INS. Second openings OP2, which respectively overlap the first openings OP1 of the insulating layer INS, may be formed on the thin film layer TFL. The area of each of the second openings OP2 may be smaller than the area of each of the first openings OP1 defined by the upper surface of the insulating layer INS that is in contact with the thin film layer TFL. Accordingly, a tip T structure protruding from the insulating layer INS toward the first opening OP1 may be formed in the thin film layer TFL due to the second opening OP2. In an embodiment, a thin film layer TFL may be made of a metal. For example, the thin film layer TFL may be made of niobium with excellent etching selectivity.

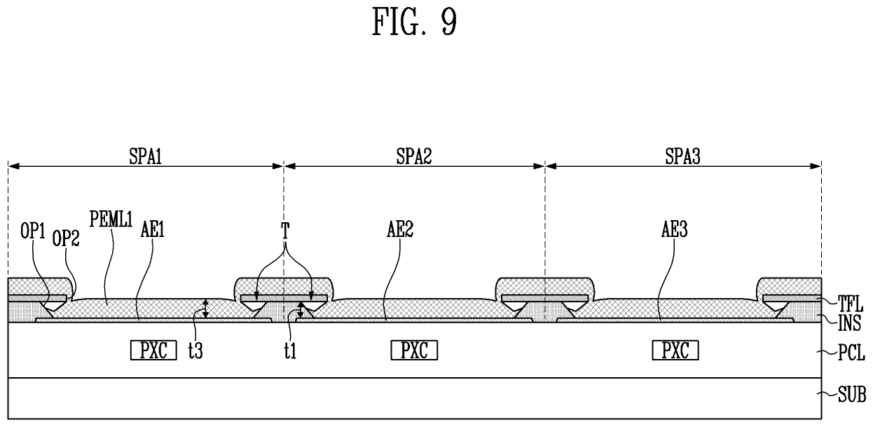

Referring to FIG. 9, a first preliminary light-emitting layer PEML1 may be formed on the first to third anode electrodes AE1 to AE3 and the thin film layer TFL as a whole. At this time, the thickness t3 of the first preliminary light-emitting layer PEML1 may be larger than the thickness t1 of the part of the insulating layer INS, which is disposed between the first to third anode electrodes AE1 to AE3 and the thin film layer TFL. Accordingly, the part of the first preliminary light-emitting layer PEML1, which is disposed on each of the first to third anode electrodes AE1 to AE3 inside the first opening OP1, may be connected to the part of the first preliminary light-emitting layer PEML1, which is disposed on the thin film layer TFL inside the first opening OP1, without separation from each other. As such, the first preliminary light-emitting layer PEML1 may be seamlessly connected as a whole.

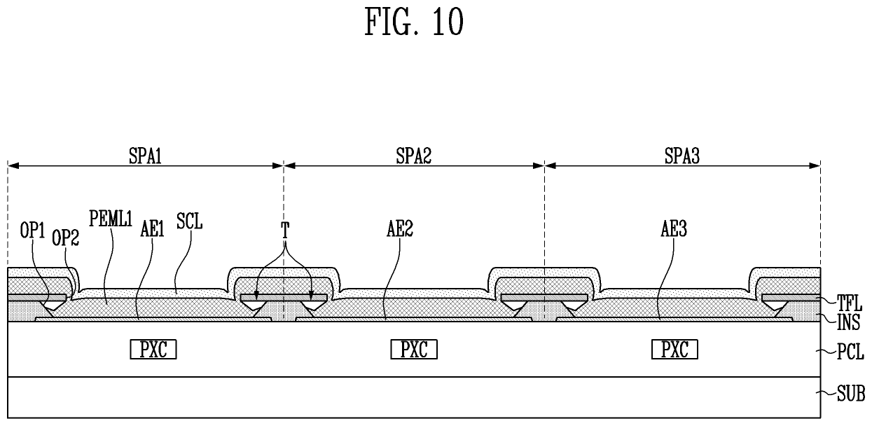

Referring to FIG. 10, a sacrificial layer SCL may be formed overall on the first preliminary light-emitting layer PEML1. The sacrificial layer SCL may play a role in protecting the first preliminary light-emitting layer PEML1 during the manufacturing process on the first preliminary light-emitting layer PEML1. The sacrificial layer SCL may be formed through a thermal deposition process. At this time, the sacrificial layer SCL may be formed of at least one of aluminum and silver, which are materials capable of thermal deposition.

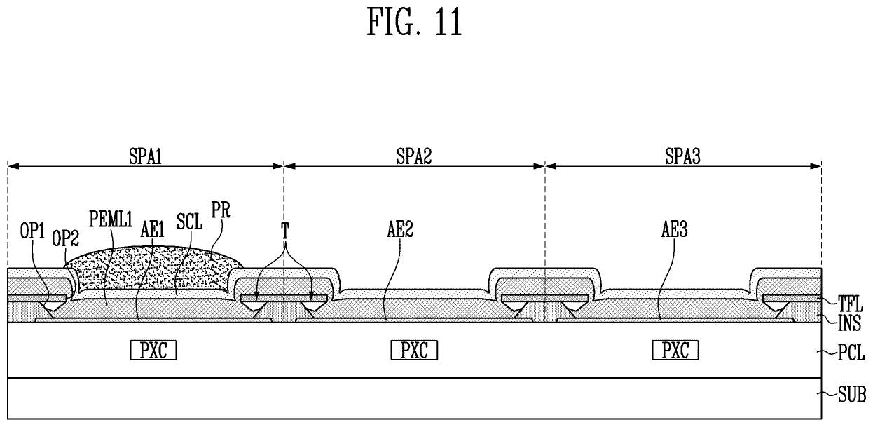

Referring to FIG. 11, a photoresist pattern PR may be formed on the sacrificial layer SCL. The photoresist pattern PR may be formed in the first sub-pixel area SPA1 and overlap the second opening OP2. The photoresist pattern PR may be formed only in the first sub-pixel area SPA1 in order to leave only the first preliminary light-emitting layer PEML1 disposed in the first sub-pixel area SPA1.

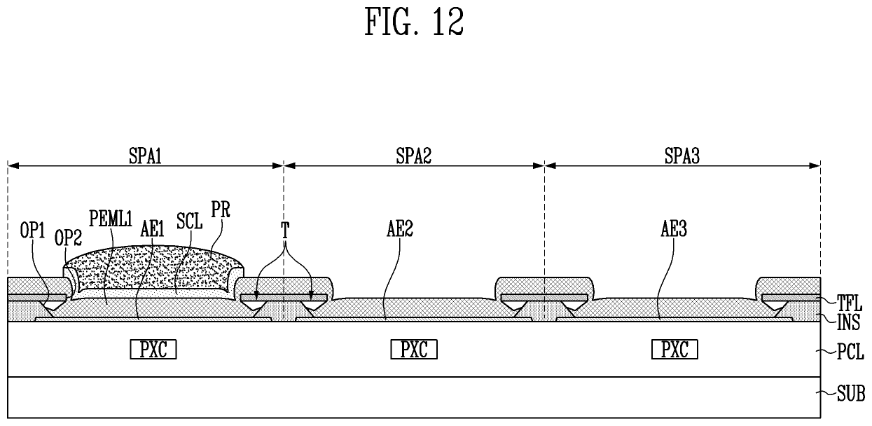

Referring to FIG. 12, the sacrificial layer SCL may be partially etched using a photoresist pattern PR. In other words, the rest of the SCL may be etched except for the part that overlaps the second opening OP2 disposed in the first sub-pixel area SPA1 of the SCL.

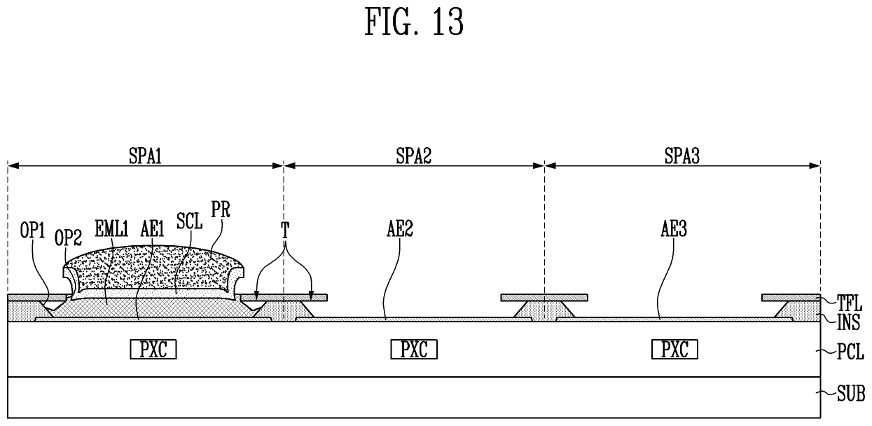

Referring to FIG. 13, the first preliminary light-emitting layer PEML1 may be partially etched using a photoresist pattern PR. In other words, the remaining part may be etched except for the part of the first preliminary light-emitting layer PEML1, which is disposed in the first opening OP1 disposed in the first sub-pixel area SPA1, and the part connected to the tip T of the thin film layer TFL. Accordingly, a first light-emitting layer EML1, which is disposed in the first opening OP1 on the first anode electrode AE1 and is directly connected to the tip T of the thin film layer TFL, may be formed in the first sub-pixel area SPA1.

At this time, the sacrificial layer SCL and the primary preliminary light-emitting layer PEML1 may be etched under different conditions. As the sacrificial layer SCL and the first preliminary light-emitting layer PEML1 are etched under different conditions, the etching process of the sacrificial layer SCL and the etching process of the first preliminary light-emitting layer PEML1 may be controlled separately so that the etching quality of the sacrificial layer SCL and the first preliminary light-emitting layer PEML1 may be further improved.

In case that the sacrificial layer SCL and the first preliminary light-emitting layer PEML1 are etched, the first thin film layer TFL may not be etched. Since the first thin film layer TFL is made of a material with a higher etching selectivity ratio than the sacrificial layer SCL and the first preliminary light-emitting layer PEML1, even if the sacrificial layer SCL or the first preliminary light-emitting layer PEML1 is etched, the first thin film layer TFL may not be etched and not damaged during the manufacturing process of the light-emitting layer.

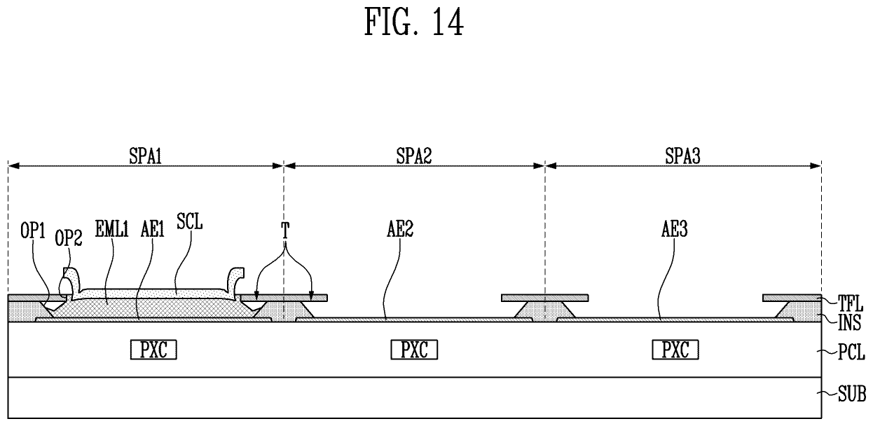

Referring to FIG. 14, the photoresist pattern PR may be removed. Accordingly, the process of forming the first light-emitting layer EML1 may be completed.

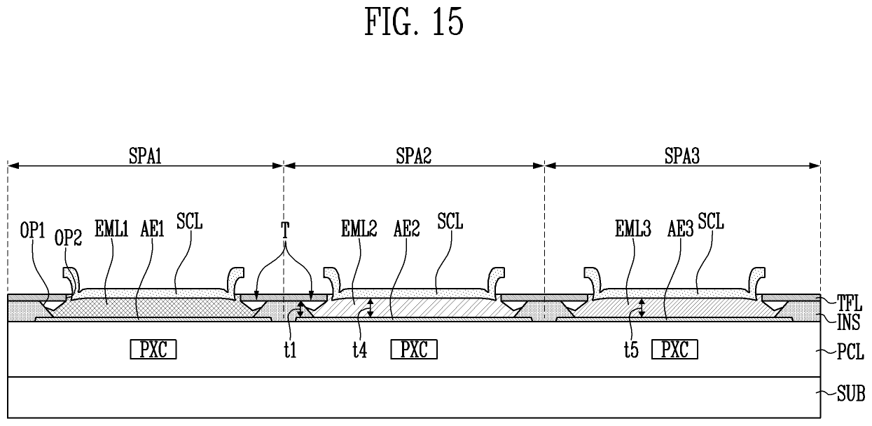

Referring to FIG. 15, after the process of forming the first light-emitting layer EML1, the process of forming the second light-emitting layer EML2 and the process of forming the third light-emitting layer EML3 may be performed. Each of the second light-emitting layer EML2 and the third light-emitting layer EML3 may be formed by repeating the same process as the one that forms the first light-emitting layer EML1 described above.

Accordingly, the second light-emitting layer EML2, which is disposed in the first opening OP1 on the second anode electrode AE2 and is connected to the tip T of the thin film layer TFL, may be formed in the second sub-pixel area SPA2. The third light-emitting layer EML3, which is disposed in the first opening OP1 on the third anode electrode AE3 and is connected with the tip T of the thin film layer TFL, may be formed in the third sub-pixel area SPA3. After each first to third light-emitting layer EML1 to EML3 is formed, a sacrificial layer SCL may be formed on each of the first to third light-emitting layers EML1 to EML3.

At this time, each of the thicknesses t4 and t5 of the second and third light-emitting layers EML2 and EML3 may be larger than the thickness t1 of the part of the insulating layer INS, which is disposed between the first to third anode electrodes AE1 to AE3 and the thin film layer TFL. Thus, the thickness t1 of the part of the insulating layer INS, which is disposed between each of the first to third anode electrodes AE1 to AE3 and the thin film layer TFL, may always be less than the thicknesses t3 to t5 of the first to third light-emitting layers EML1 to EML3. Accordingly, the first to third anode electrodes AE1 to AE3 may be stably connected to the thin film layer TFL and formed.

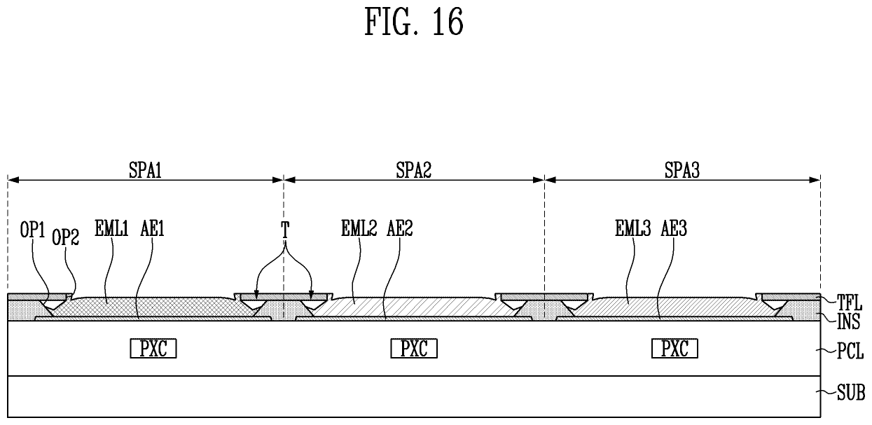

Referring to FIG. 16, since the first to third light-emitting layers EML1 to EML3 have been manufactured, the sacrificial layer SCL on each of the first to third light-emitting layers EML1 to EML3 may be removed. Accordingly, the first to third light-emitting layers EML1 to EML3 overlapping the second openings OP2 may be exposed.

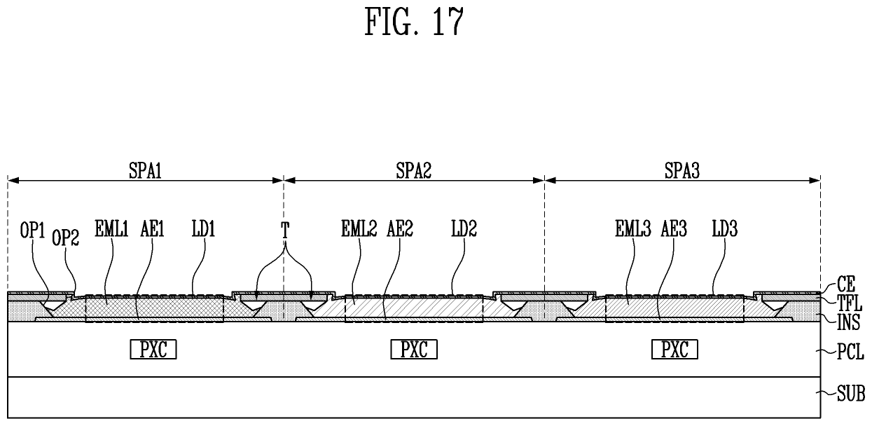

Referring to FIG. 17, the cathode electrode CE may be formed overall on the first to third light-emitting layers EML1 to EML3 and the thin film layer TFL. The cathode electrode CE may be disposed overall on the first to third sub-pixel areas SPA1 to SPA3.

In this way, the first anode electrode AE1, the first light-emitting layer EML1, and the cathode electrode CE, which are disposed in the first sub-pixel area SPA1, may form a first light-emitting element LD1, the second anode electrode AE2, the second light-emitting layer EML2, and the cathode electrode CE, which are disposed in the second sub-pixel area SPA2, may form a second light-emitting element LD2, and the third anode electrode AE3, the third light-emitting layer EML3, and the cathode electrode CE, which are disposed in the third sub-pixel area SPA3, may form a third light-emitting element LD3.

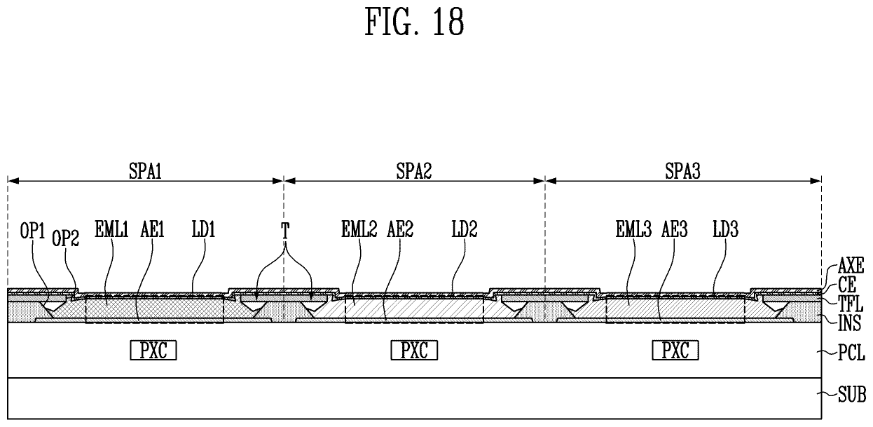

Referring to FIG. 18, the auxiliary electrode AXE may be formed on the cathode electrode CE. The auxiliary electrode AXE may overall overlap the cathode electrode CE.

The auxiliary electrode AXE may be formed through a sputtering process. As such, the step coverage of the auxiliary electrode AXE may be improved so that the auxiliary electrode AXE may be overall extended without any disconnections. Thus, even if there is a disconnection in the cathode electrode CE, the cathode electrode CE may be connected as a whole via the auxiliary electrode AXE.

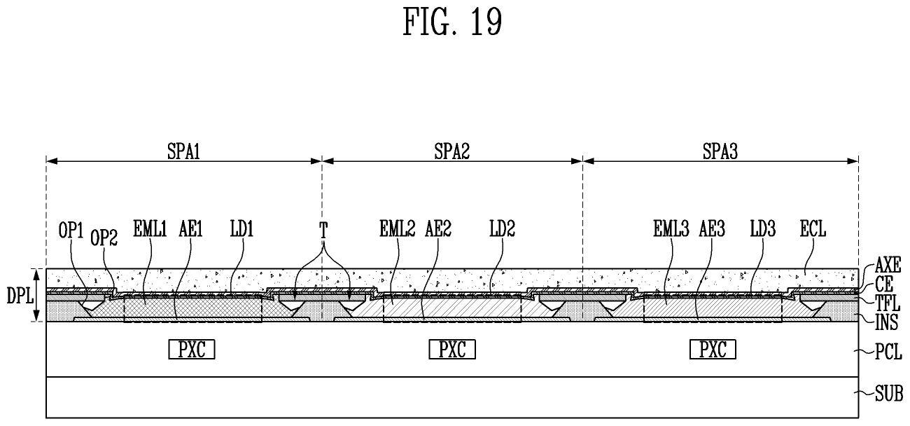

Referring to FIG. 19, an encapsulation layer ECL may be formed on the auxiliary electrode AXE. The encapsulation layer ECL may cover the auxiliary electrode AXE as a whole. Accordingly, the display element layer DPL may be formed.

In an embodiment, the thin film layer TFL may have a tip structure, and the thin film layer TFL may be formed of a metal with a higher etching selectivity ratio than the sacrificial layer SCL, so that the thin film layer TFL may be connected to the first to third light-emitting layers EML1 to EML3 without being damaged during the manufacturing process. Accordingly, the cathode electrode CE and the auxiliary electrode AXE may be extended in their entirety without disconnection.

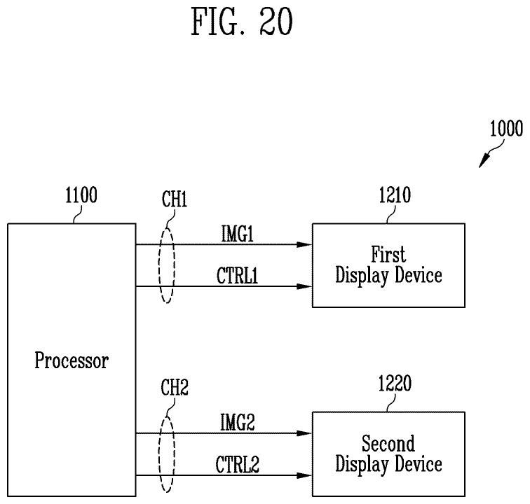

FIG. 20 is a block diagram illustrating an embodiment of a display system (or electronic device).

Referring to FIG. 20, a display system 1000 may include a processor 1100 and one or more display devices 1210 and 1220.

The processor 1100 may perform a variety of tasks and calculations. In embodiments, the processor 1100 may include an application processor, a graphics processor, a microprocessor, a central processing unit, and so on. The processor 1100 may be connected to other components of the display system 1000 via a bus system and control the components.

Referring to FIG. 20, the display system 1000 is shown to include the first and second display devices 1210 and 1220. The processor 1100 may be connected to the first display device 1210 via the first channel CH1 and may be connected to the second display device 1220 via the second channel CH2.

Through the first channel CH1, the processor 1100 may transmit the first image data IMG1 and the first control signal CTRL1 to the first display device 1210. The first display device 1210 may display images based on the first image data IMG1 and the first control signal CTRL1. The first display device 1210 may be configured in the same way as the display device 100 described with reference to FIG. 1. The first image data IMG1 and the first control signal CTRL1 may be provided as the input image data IMG and the control signal CTRL respectively in FIG. 1.

Through the second channel CH2, the processor 1100 may transmit the second image data IMG2 and the second control signal CTRL2 to the second display device 1220. The second display device 1220 may display images based on the second image data IMG2 and the second control signal CTRL2. The second display device 1220 may be configured as in the display device 100 described with reference to FIG. 1. The second image data IMG2 and the second control signal CTRL2 may be provided as input image data IMG and the control signal CTRL respectively in FIG. 1.

The display system (or electronic device) 1000 may include the display device DD. The display system (or electronic device) 1000 may include an organic light-emitting display apparatus, an inorganic light-emitting display apparatus, a quantum dot light-emitting display apparatus, display screens of portable electronic apparatus, such as mobile phones, smartphones, tablet personal computers (PCs), mobile communication terminals, electronic notebooks, electronic books, portable multimedia players (PMPs), navigation devices, and ultra mobile PCs (UMPCs), display screens of televisions, notebooks, monitors, advertisement panels, Internet of things (IoT) devices, a portable communication device a smartphone, a computer device, a portable multimedia device, a portable medical device, a camera, a wearable device, and a home appliance. For example, the display system (or electronic device) 1000 may include a portable computer, and computing systems that provide image display functions such as a smart watch, a watch phone, etc. The display system 1000 may include at least one of a head mounted display (HMD), a virtual reality (VR) device, a mixed reality (MR) device, and an augmented reality (AR) device.

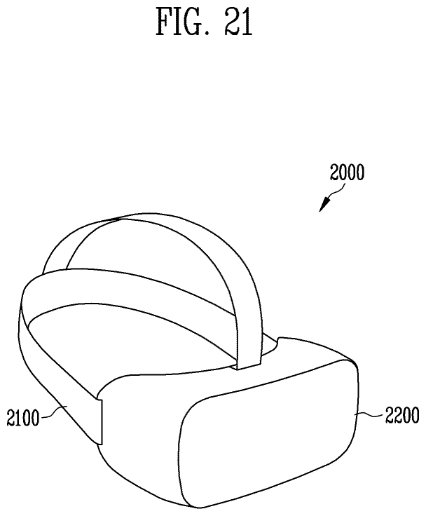

FIG. 21 is a schematic perspective view illustrating an example of application of the display system (or electronic device) of FIG. 20.

Referring to FIG. 21, the display system 1000 of FIG. 20 may be applied to a head-mounted display device 2000. The head-mounted display device 2000 may be a wearable electronic device that may be worn on the user's head.

The head-mounted display device 2000 may include a head-mounted band 2100 and a display storage case 2200. The head-mounted band 2100 may be connected to the display storage case 2200. The head-mounted band 2100 may include a horizontal band and/or a vertical band for fixing the head-mounted display device 2000 to the user's head. The horizontal band may surround the side part of the user's head, and the vertical band may surround the upper part of the user's head. However, embodiments are not limited thereto. For example, the head-mounted band 2100 may be implemented in the form of a frame, helmet, etc.

The display storage case 2200 may accommodate the first and second display devices 1210 and 1220 of FIG. 20. The display storage case 2200 may further accommodate the processor 1100 of FIG. 20.

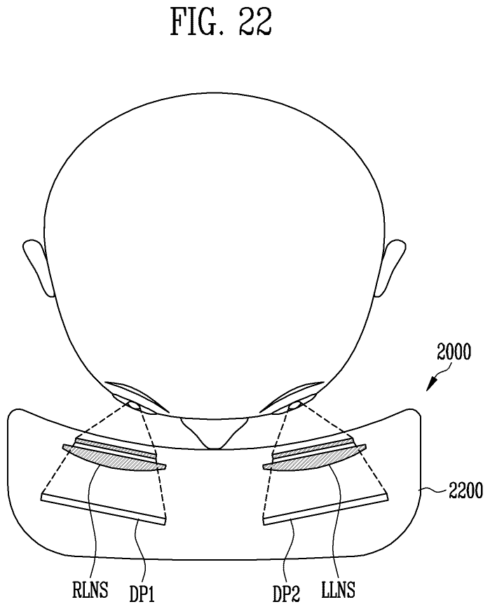

FIG. 22 is a diagram illustrating a head-mounted display device worn by the user of FIG. 21.

Referring to FIG. 22, the first display panel DP1 of the first display device 1210 and the second display panel DP2 of the second display device 1220 may be disposed in the head-mounted display device 2000. The head-mounted display device 2000 may further include one or more lenses LLNS and RLNS.

The right eye lens RLNS may be disposed between the first display panel DP1 and the user's right eye in the display storage case 2200. The left eye lens LLNS may be disposed between the second display panel DP2 and the user's left eye in the display storage case 2200.

The image, which is output from the first display panel DP1, may be displayed in the right eye of the user through the right eye lens RLNS. The right eye lens RLNS may refract light from the first display panel DP1 to be directed to the user's right eye. The right eye lens RLNS may perform an optical function to control the viewing distance between the first display panel DP1 and the user's right eye.

The image, which is output from the second display panel DP2, may be displayed in the user's left eye via a left eye lens LLNS. The left eye lens LLNS may refract light from the second display panel DP2 to be directed toward the user's left eye. The left eye lens LLNS may perform an optical function to control the viewing distance between the second display panel DP2 and the user's left eye.

In an embodiment, the right eye lens RLNS and the left eye lens LLNS may each include an optical lens having a pancake-shaped cross-section. In an embodiment, the right eye lens RLNS and the left eye lens LLNS may each include a multi-channel lens including sub-areas with different optical properties. Each display panel outputs images corresponding to each of the sub-areas of the multi-channel lens, and the output images may be displayed to the user through each of the corresponding sub-areas.

While the disclosure has been described in detail in accordance with the aforementioned embodiments, it should be noted that the embodiments are for illustrative purposes and do not limit the scope of the disclosure. A person skilled in the art to which the disclosure pertains will be able to understand that various examples of variations are possible within the scope of the disclosure.

The scope of the disclosure is not limited to what is described in the detailed description of the specification, but is also determined by the appended claims. The meaning and scope of the claims, and any variations or modifications are to be construed as to fall within the scope of the disclosure.

What is claimed is:

1. A display device comprising:
an anode electrode disposed on a substrate;
an insulating layer disposed on the substrate, the insulating layer covering an edge of the anode electrode, and the insulating layer having a first opening overlapping the anode electrode;
a thin film layer disposed on the insulating layer, the thin film layer comprising a tip protruding toward the first opening, and the thin film layer having a second opening defined by the tip;
a light-emitting layer disposed on the anode electrode, the light-emitting layer disposed inside of the first opening, and directly contacting the tip of the thin film layer; and
a cathode electrode disposed over the light-emitting layer and the thin film layer.

2. The display device of claim 1, wherein a thickness of the insulating layer disposed between the anode electrode and the thin film layer is less than or equal to a thickness of the light-emitting layer.

3. The display device of claim 2, wherein the thickness of the insulating layer disposed between the anode electrode and the thin film layer is equal to or less than about 1500 Å.

4. The display device of claim 1, wherein the thin film layer comprises a metal.

5. The display device of claim 4, wherein the thin film layer comprises at least one of niobium, titanium, tantalum, and titanium nitride.

6. The display device of claim 1, wherein the insulating layer comprises an inorganic material.

7. The display device of claim 6, wherein the insulating layer comprises at least one of silicon oxide and silicon nitride.

8. The display device of claim 1, further comprising an auxiliary electrode extending over the cathode electrode.

9. The display device of claim 8, wherein the auxiliary electrode comprises a transparent conductive oxide.

10. A method of manufacturing a display device, the method comprising:
forming an anode electrode on a substrate;
forming an insulating layer covering an edge of the anode electrode, the insulating layer having a first opening overlapping the anode electrode on the substrate;
forming a thin film layer comprising a tip protruding toward the first opening, the thin film layer having a second opening defined by the tip on the insulating layer;
forming a light-emitting layer disposed inside of the first opening and directly contacting the tip of the thin film layer on the anode electrode; and
forming a cathode electrode disposed over the light-emitting layer and the thin film layer.

11. The method of claim 10, wherein a thickness of the light-emitting layer is formed greater than a thickness of the insulating layer disposed between the anode electrode and the thin film layer.

12. The method of claim 11, wherein the forming of the light-emitting layer comprises:
forming a preliminary light-emitting layer extending over the anode electrode and the thin film layer;
forming a sacrificial layer extending over the preliminary light-emitting layer;
forming a photoresist pattern overlapping the second opening on the sacrificial layer;
partially etching the sacrificial layer using the photoresist pattern;
forming the light-emitting layer by partially etching the preliminary light-emitting layer using the photoresist pattern;
removing the photoresist pattern; and
removing the sacrificial layer.

13. The method of claim 12, wherein the sacrificial layer is formed of at least one of aluminum and silver.

14. The method of claim 12, wherein the sacrificial layer and the preliminary light-emitting layer are etched under different conditions.

15. The method of claim 12, wherein the forming of the sacrificial layer is performed through a thermal deposition process.

16. The method of claim 10, further comprising forming an auxiliary electrode overlapping the cathode electrode.

17. The method of claim 16, wherein the forming of the auxiliary electrode is performed through a sputtering process.

18. An electronic device comprising:
a display device comprising:
an anode electrode disposed on a substrate;
an insulating layer disposed on the substrate, the insulating layer covering an edge of the anode electrode, and the insulating layer having a first opening overlapping the anode electrode;
a thin film layer disposed on the insulating layer, the thin film layer comprising a tip protruding toward the first opening, and the thin film layer having a second opening defined by the tip;
a light-emitting layer disposed on the anode electrode, the light-emitting layer disposed inside of the first opening, and directly contacting the tip of the thin film layer; and
a cathode electrode disposed over the light-emitting layer and the thin film layer.
